(19) United States
(12) Patent Application Publication
(10) Pub. No.: US 2022/0310953 A1
(43) Pub. Date: Sep. 29, 2022

(54) QUANTUM DOT MATERIAL, QUANTUM DOT LIGHT-EMITTING DEVICE, DISPLAY DEVICE AND MANUFACTURING METHOD

(71) Applicants: Beijing BOE Technology Development Co., Ltd., Beijing (CN); BOE Technology Group Co., Ltd., Beijing (CN)

(72) Inventor: Dong LI, Beijing (CN)

(21) Appl. No.: 17/517,252

(22) Filed: Nov. 2, 2021

(30) Foreign Application Priority Data
Mar. 26, 2021 (CN) 202110328528.1

(51) Int. Cl. H01L 51/50; H01L 51/00

(52) U.S. Cl. CPC H01L 51/502; H01L 51/0002; H01L 51/504; H01L 51/56

(57) ABSTRACT

The present disclosure discloses a quantum dot material, a quantum dot light-emitting device, a display device, and a manufacturing method to solve the problems in the prior art that carrier transport is hindered, the electrical performance of the device is reduced, and the luminous efficiency is reduced after a quantum dot film layer is patterned. The quantum dot material includes: a quantum dot body, linkers, and first ligands; wherein one ends of the linkers are connected with the quantum dot body, and the other ends of the linkers are connected with the first ligands; and each first ligand includes one or a combination of:

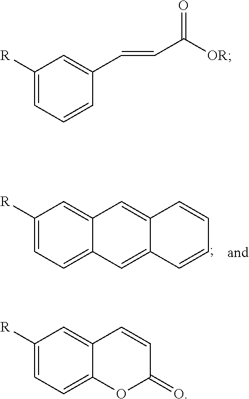

### CROSS-REFERENCE TO RELATED APPLICATION

This application is based on and claims priority under 35 U.S.C. 119 to Chinese Patent Application No. 202110328528.1, filed on Mar. 26, 2021, in the China National Intellectual Property Administration. The entire disclosure of the above application is incorporated herein by reference.

### FIELD

The present disclosure relates to the technical field of semiconductors, in particular to a quantum dot material, a quantum dot light-emitting device, a display device and a manufacturing method.

### BACKGROUND

Quantum dots (QDs), as a new light-emitting material, have the advantages of high light color purity, high luminous quantum efficiency, adjustable light-emitting color, and long service life. At present, QDs have become a research hotspot of new LED light-emitting materials. Therefore, quantum dot light emitting diodes (QLEDs) with a quantum dot material as a light-emitting layer have become the main research direction of new display devices at present.

### SUMMARY

Some embodiments of the present disclosure provide a quantum dot material, including: a quantum dot body, a linker, and a first ligand; wherein one end of the linker is connected with the quantum dot body, and the other end of the linker is connected with the first ligand; and the first ligand includes one or a combination of:

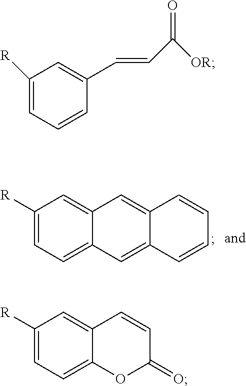

wherein R includes one or a combination of:
an alkyl chain;
an aromatic ring; and
a heterocycle.

In one possible embodiment, each linker includes a first connection structure, and a second connection structure; one end of the first connection structure is connected with the quantum dot body, and the other end of the first connection structure is connected with one end of the second connection structure; and the other end of the second connection structure is connected with the first ligands.

In one possible embodiment, the first connection structure includes one of:
—SH;
—COOH; or
—NH₂.

In one possible embodiment, the second connection structure includes an alkyl chain.

Some embodiments of the present disclosure also provide a quantum dot light-emitting device, including: a substrate, and a quantum dot film layer located at one side of the substrate and having a plurality of pattern portions; wherein each pattern portion includes the quantum dot material provided by above embodiments of the present disclosure.

In one possible embodiment, the first ligands of the pattern portions are crosslinked by different first ligands within the pattern portions when irradiated with light of a first wavelength band, and decrosslinked when irradiated with light of a second wavelength band.

In one possible embodiment, a functional layer is further arranged between the substrate and the quantum dot film layer; one side, facing the quantum dot film layer, of the functional layer is connected with siloxane bodies and second ligands connected with the siloxane bodies; and
the first ligands of the pattern portions are identical to the second ligands in the corresponding region.

In one possible embodiment, the first ligands of the pattern portions are crosslinked with the second ligands in the corresponding region when irradiated with light of a first wavelength band and decrosslinked when irradiated with light of a second wavelength band.

In one possible embodiment, the quantum dot light-emitting device includes at least two types of the pattern portions having different light emission colors, the first ligands of the pattern portions are identical with each other, and the second ligands of the functional layer are identical with each other.

In one possible embodiment, the quantum dot light-emitting device includes at least two types of the pattern portions having different light emission colors, the first ligands of the pattern portions having the same light emission color are identical with each other and the first ligands of the pattern portions having different light emission colors are different from each other.

In one possible embodiment, a first electrode layer is arranged between the substrate and the functional layer, and a second electrode layer is arranged at one side, deviating from the functional layer, of the quantum dot film layer.

Some embodiments of the present disclosure also provide a display device, including the quantum dot light-emitting device provided by above embodiments of the present disclosure.

Some embodiments of the present disclosure provide a manufacturing method for the quantum dot light-emitting device provided by above embodiments of the present disclosure, including:
providing a substrate;
forming a quantum dot film having at least one light emission color on one side of the substrate, and irradiating with light of a first wavelength band to carry out crosslinking in an irradiated region, so as to form a plurality of pattern portions; and
irradiating the pattern portions with light of a second wavelength band to carry out decrosslinking in the pattern portions.

In one possible embodiment, the forming the quantum dot film having at least one light emission color on one side of the substrate, and irradiating with the light of the first wavelength band to carry out crosslinking in the irradiated region, so as to form the plurality of the pattern portions includes:
forming the quantum dot film having at least one light emission color on one side of the substrate, and irradiating with the light of the first wavelength band to crosslink different first ligands within the quantum dot film in the irradiated region to form the plurality of the pattern portions.

In one possible embodiment, before the forming the quantum dot film having at least one light emission color on one side of the substrate, the manufacturing method further includes: forming a functional layer on one side of the substrate, wherein one side, deviating from the substrate, of the functional layer is connected with siloxane bodies and second ligands connected with the siloxane bodies; and
The forming the quantum dot film having at least one light emission color on one side of the substrate, and irradiating with the light of the first wavelength band to carry out crosslinking in the irradiated region, so as to form the plurality of the pattern portions includes:
forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions.

In one possible embodiment, the forming the functional layer on one side of the substrate includes: forming the functional layer on one side of the substrate so that the functional layer and the pattern portions having different light emission colors corresponds to same second ligands;
the forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions includes:
irradiating with the light of the first wavelength band through shielding of a mask to crosslink the first ligands of the quantum dot film in the irradiated region with the second ligands of the functional layer in the corresponding region, during forming the quantum dot film of each light emission color, and removing the quantum dot film where crosslinking is not carried out to form the plurality of the pattern portions having one light emission color; and
repeating the above steps for a plurality of times to form the pattern portions having a plurality of light emission colors.

In one possible embodiment, the forming the functional layer on one side of the substrate includes: forming the functional layer on one side of the substrate so that the functional layer and the pattern portions having different light emission colors corresponds to different second ligands; and
the forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions includes:
forming a plurality of quantum dot films having different light emission colors;
irradiating with the light of the first wavelength band once to crosslink the second ligands of the functional layer in different regions with the first ligands of the quantum dot films in corresponding regions; and
removing the quantum dot films where crosslinking is not carried out to form the plurality of the pattern portions.

### BRIEF DESCRIPTION OF THE DRAWINGS

FIG. 1 is a structural schematic diagram of a quantum dot material provided by embodiments of the present disclosure;

FIG. 2 is a first structural schematic diagram of a quantum dot device provided by embodiments of the present disclosure;

FIG. 3 is a second structural schematic diagram of the quantum dot device provided by embodiments of the present disclosure;

FIG. 4 is a third structural schematic diagram of the quantum dot device provided by embodiments of the present disclosure;

FIG. 5 is a fourth structural schematic diagram of the quantum dot device provided by embodiments of the present disclosure;

FIG. 6 is a first flow diagram of manufacturing of the quantum dot device provided by embodiments of the present disclosure;

FIG. 7 is a second flow diagram of manufacturing of the quantum dot device provided by embodiments of the present disclosure;

FIG. 8 is a third flow diagram of manufacturing of the quantum dot device provided by embodiments of the present disclosure;

FIG. 9 is a schematic diagram of crosslinking within a quantum dot film layer provided by embodiments of the present disclosure;

FIG. 10 is a fourth flow diagram of manufacturing of the quantum dot device provided by embodiments of the present disclosure; and

FIG. 11 is a fifth flow diagram of manufacturing of the quantum dot device provided by embodiments of the present disclosure.

### DETAILED DESCRIPTION OF THE EMBODIMENTS

In order to make the objects, technical solutions and advantages of the embodiments of the present disclosure more clear, the technical solutions of the embodiments of the present disclosure will be clearly and completely described below in conjunction with the accompanying drawings of the embodiments of the present disclosure. Obviously, the described embodiments are part of the embodiments of the present disclosure, rather than all of the embodiments. Based on the described embodiments of the present disclosure, all other embodiments obtained by those of ordinary skill in the art without inventive effort fall within the scope of protection of the present disclosure.

Unless otherwise defined, the technical or scientific terms used in the present disclosure should have the general meanings understood by those of ordinary skill in the art to which the present disclosure belongs. “First”, “second” and similar terms used in the present disclosure do not mean any order, quantity or importance, but are only used to distinguish different components. Similar terms such as “including” or “comprising” mean that elements or objects appearing before the term encompass elements or objects listed after the term and equivalents thereof, without excluding other elements or objects. Similar terms such as “connection” or “connected” are not limited to physical or mechanical connections, but can include electrical connections, whether direct or indirect. “Upper”, “lower” “left”, “right” and the like are only used to indicate relative positional relationships, which may change accordingly when the absolute positions of the described objects change.

To keep the following description of the embodiments of the present disclosure clear and concise, the present disclosure omits detailed descriptions of known functions and known components.

In mass production, patterning of QDs mainly adopts an ink-jet printing process, but limited by equipment, its resolution is limited to 200 ppi or below, so a higher-resolution patterning method is required. The traditional patterning methods using a lithography process are divided into a direct method and an indirect method. The indirect method usually needs to use a photoresist to form a pixel groove, and then strip the photoresist after coating with quantum dots. This method generally has photoresist residue, which affects the electrical performance of the device. The direct method is to introduce a photocrosslinking group into quantum dot ligands to crosslink the ligands under certain conditions and change their solubility, so as to leave quantum dots in specific places.

In the process of forming the patterned quantum dot film layer by the indirect method, crosslinking of ligands together typically changes the ligand structure, i.e., the ligand structure is different before and after crosslinking, and the crosslinking system causes some hindrance to the transport of holes and electrons, thereby affecting the electrical performance of the device, while the earlier electrical optimization results are no longer applicable after crosslinking of the quantum dots, resulting in a decrease in the luminous efficiency of the quantum dot film layer.

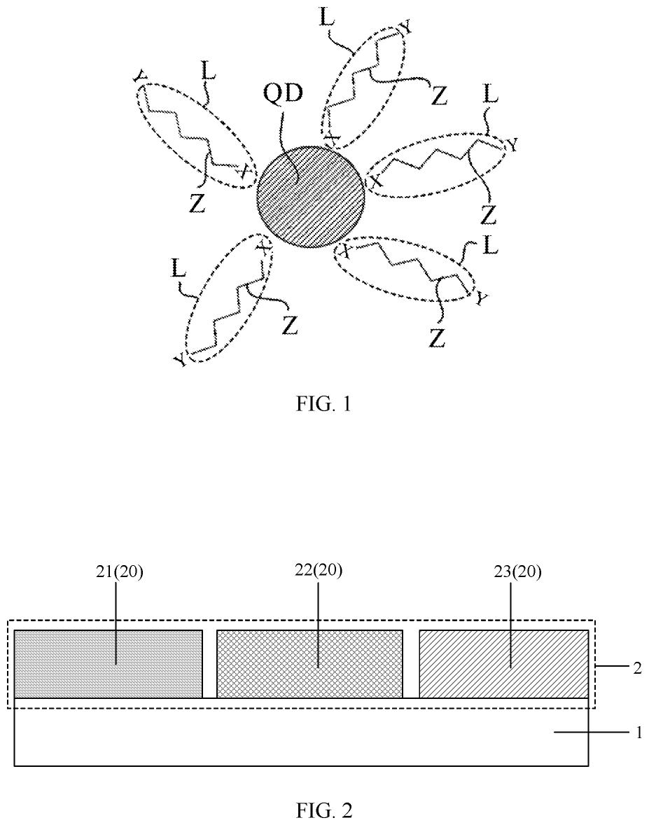

In view of this, referring to FIG. 1, the embodiments of the present disclosure provide a quantum dot material, including: a quantum dot body QD, linkers L, and first ligands Y; wherein one ends of the linkers L are connected with the quantum dot body QD and the other ends of the linkers L are connected with the first ligands Y; and each first ligand Y includes one or a combination of:

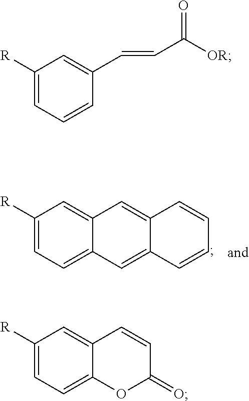

wherein R includes one or a combination of:
an alkyl chain;
an aromatic ring; and
a heterocycle.

According to the quantum dot material provided by embodiments of the present disclosure, the first ligands form a reversible photoresponsive crosslinking system, and may be crosslinked when irradiated with the light of the first wavelength band, and decrosslinked when irradiated with the light of the second wavelength band, so that when the patterned quantum dot film layer is formed by the quantum dot material provided by the embodiments of the present disclosure, in the patterning process, crosslinking may be carried out in the irradiated region by irradiating with the light of the first wavelength band, so the quantum dot material is not easily removed during subsequent cleaning, while the quantum dot material in a region where crosslinking is not carried out can be removed during cleaning, thereby realizing patterning of the quantum dot film layer, after patterning, decrosslinking may be carried out in the region where crosslinking is carried out by irradiating with the light of the second wavelength band, thereby realizing the patterning of the quantum dot film layer, and while avoiding the influence of the crosslinked structure on the carrier transport performance, so as to improve the problems in the prior art that carrier transport is hindered, the electrical performance of the device is reduced, and the luminous efficiency is reduced after the quantum dot film layer is patterned.

In one possible embodiment, as shown in FIG. 1, each linker L includes a first connection structure X, and a second connection structure Z; one end of the first connection structure X is connected with the quantum dot body QD, and the other end of the first connection structure X is connected with one end of the second connection structure Z; and the other end of the second connection structure is are connected with the first ligand Y.

In one possible embodiment, each first connection structure X may include one of:
—SH;
—COOH; or
—NH₂.

In some embodiments of the present disclosure, each first connection structure X may include —SH, —COOH, or —NH₂, which may enable connection to the quantum dot body QD.

In one possible embodiment, each second connection structure Z may include an alkyl chain. Alternatively, the second connection structure Z may also include other carbon skeletons.

Optionally, for example, when each first ligand Y includes

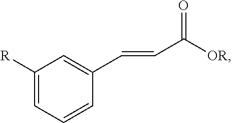

the crosslinking and decrosslinking of the first ligands Y may be:

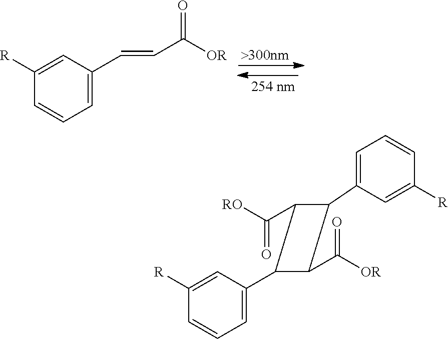

Optionally, for example, when each first ligand Y includes

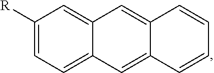

the crosslinking and decrosslinking of the first ligands Y may be:

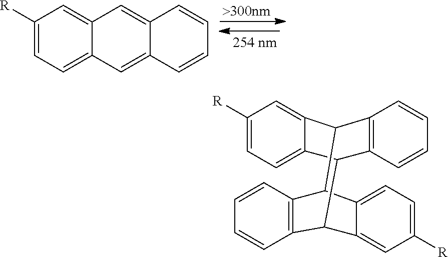

Optionally for example, when each first ligand Y includes

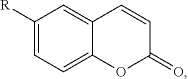

the crosslinking and decrosslinking of the first ligands Y may be:

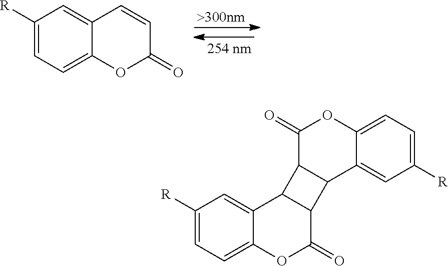

Based on the same inventive concept, referring to FIG. 2, some embodiments of the present disclosure also provide a quantum dot light-emitting device, including: a substrate 1, and a quantum dot film layer 2 located at one side of the substrate 1 and having a plurality of pattern portions 20; wherein each pattern portion 20 includes the quantum dot material provided by embodiments of the present disclosure, and the ligands of the pattern portions 20 are crosslinked when irradiated with light of a first wavelength band, and decrosslinked when irradiated with light of a second wavelength band. The quantum dot light-emitting device may be an electroluminescent device or may be a photoluminescent device. Optionally, the quantum dot light-emitting device may be quantum dot light emitting diodes (QLEDs) or may be quantum dot photoluminescent units (e.g., quantum dot color conversion units in a QD-OLED display device).

In one possible implementation, the plurality of the pattern portions of the quantum dot light-emitting device may be pattern portions with the same light emission color, and the quantum dot light-emitting device is a quantum dot device emitting monochromatic light; the quantum dot light-emitting device may include at least two pattern portions having different light emission colors, for example, as shown in FIG. 2, including a first pattern portion 21 emitting red light, a second pattern portion 22 emitting green light, and a third pattern portion 23 emitting blue light, and the quantum dot light-emitting device is a display device.

In some embodiments, the pattern portions 20 may be formed by crosslinking different first ligands of the quantum dot body within the quantum dot film layer itself and then patterning, or by crosslinking first ligands of the quantum dot film layer with second ligands of the functional layer, and then patterning.

Optionally, in one possible embodiment, the first ligands Y of the pattern portions 20 are crosslinked with each other within the pattern portions 20 when irradiated with light of a first wavelength band, and decrosslinked when irradiated with light of a second wavelength band. In some embodiments of the present disclosure, patterning of the quantum dot film layer may be achieved by crosslinking different first ligands within the quantum dot film layer upon irradiation with the light of the first wavelength band.

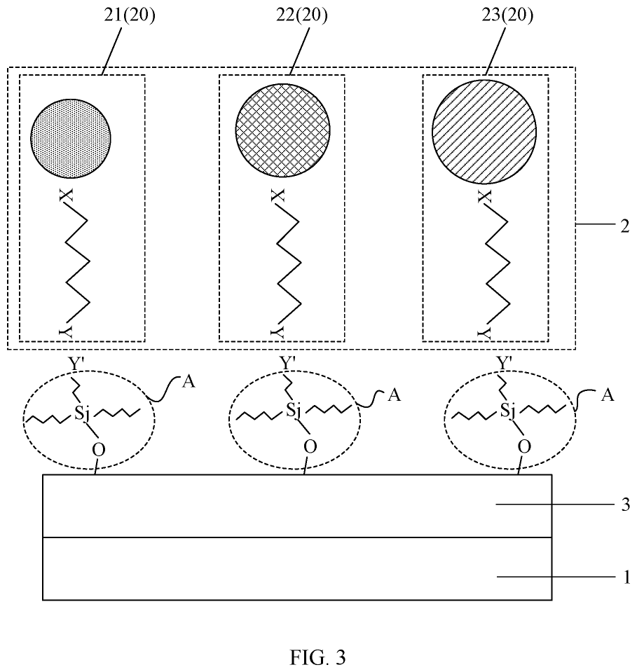

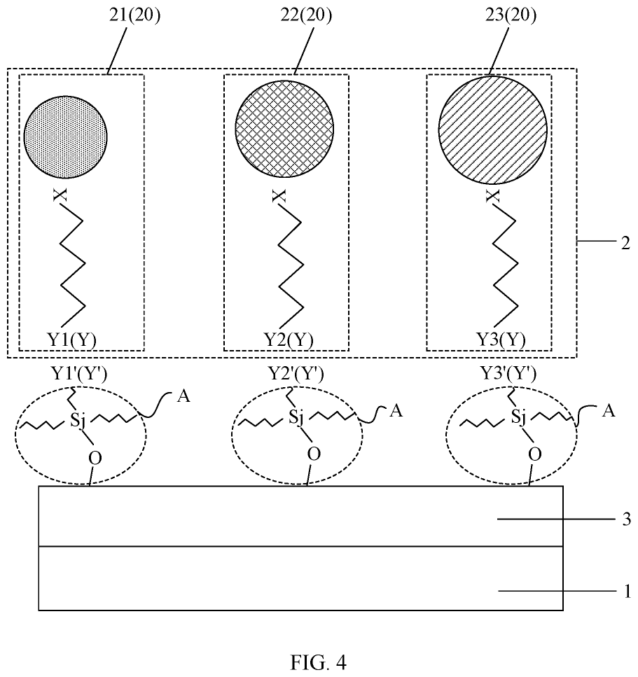

Optionally, in one possible embodiment, as shown in FIGS. 3 and 4, a functional layer 3 is further arranged between the substrate 1 and the quantum dot film layer 2; one side, facing the quantum dot film layer 2, of the functional layer 3 is connected with siloxane bodies A and second ligands Y′ connected with the siloxane bodies A; the first ligands Y of the pattern portions 20 are the same as the second ligands Y′ in the corresponding region, and the first ligands Y of the pattern portions 20 are crosslinked with the second ligands Y′ in the corresponding region when irradiated with the light of the first wavelength band and decrosslinked when irradiated with the light of the second wavelength band. Optionally, the corresponding region may be understood as a region of the functional layer 3 directly opposite to the pattern portions 20. In some embodiments of the present disclosure, the functional layer 3 is further arranged between the substrate 1 and the quantum dot film layer 2, in the process of patterning the quantum dot film layer 2, the patterning of the quantum dot film layer can be realized by crosslinking between the quantum dot film layer 2 and the functional layer 3; in addition, the siloxane bodies A arranged on one side, facing the quantum dot film layer 2, of the functional layer 3 enables the formation of the second ligands Y′ on the surface of the functional layer 3.

Optionally, the functional layer 3 may be a functional layer with —OH groups on the surface before being connected with the siloxane bodies A, for example, the functional layer 3 may be an electron transport layer, the material of the electron transport layer may be nanoparticles or a sputtered film, the material can be ZnO or ZnO doped with various metals (the doped metal can be Mg, Al, Li, Y, Zr, Sn, In, Ga, Cu, etc.), the surface of the electron transport layer can have the —OH groups, and the —OH groups can be bonded with siloxanyl chains (HO—Si—Y′) to which the second ligands Y′ are connected to form the siloxane bodies A; for another example, the functional layer 3 may also be a hole transport layer, the material of the hole transport layer may be inorganic nickel oxide, vanadium oxide, molybdenum oxide, tungsten oxide, graphene oxide and the like, the surface of the hole transport layer may have —OH groups, and the —OH groups may be bonded with siloxanyl chains (HO—Si—Y′) to which the second ligands Y′ are connected to form the siloxane bodies A.

In one possible embodiment, as shown in FIG. 3, the quantum dot light-emitting device includes at least two pattern portions having different light emission colors, the first ligands Y of all the pattern portions are the same, and all the second ligands Y′ of the functional layer 3 are the same. In some embodiments of the present disclosure, the first ligands Y of all the pattern portions are the same, all the second ligands Y′ of the functional layer 3 are the same, when the pattern portion of each light emission color is formed, irradiating with the light of the first wavelength band is performed once through shielding of a mask to crosslink the first ligands Y of the quantum dot film layer 2 with the second ligands Y′ of the functional layer 3 in the irradiated region of this color, patterning of the quantum dot film layer 2 of this color is performed, and pattern portions of other colors may be sequentially formed.

In one possible embodiment, as shown in FIG. 4, the quantum dot light-emitting device includes at least two pattern portions having different light emission colors, the first ligands Y of the pattern portions having the same light emission color are the same and the first ligands Y of the pattern portions having different light emission colors are different, for example, as shown in FIG. 4, the ligands of the first pattern portion 21 emitting red light are each Y1, the ligands of the second pattern portion 22 emitting green light are each Y2, and the ligands of the third pattern portion 23 emitting blue light are each Y3; a first ligand Y (Y1) of the first pattern portion 21 emitting red light is different from a first ligand Y (Y2) of the second pattern portion 22 emitting green light, the first ligand Y (Y1) of the first pattern portion 21 emitting red light is different from a first ligand Y (Y3) of the third pattern portion 23 emitting blue light, and the first ligand Y (Y2) of the second pattern portion 22 emitting green light is different from the first ligand Y (Y3) of the third pattern portion 23 emitting blue light. In some embodiments of the present disclosure, the first ligands Y of the pattern portions having different light emission colors are different, during forming a plurality of pattern portions having different light emission colors, first, corresponding second ligands Y′ are formed in regions of the functional layer 3 corresponding to the pattern portions having different light emission colors (for example, a second ligand Y′ formed in a region of the functional layer 3 corresponding to the first pattern portion 21 is Y1′, a second ligand Y′ formed in a region of the functional layer 3 corresponding to the second pattern portion 22 is Y2′, a second ligand Y′ formed in a region of the functional layer 3 corresponding to the third pattern portion 23 is Y3′, afterwards, by coating with a quantum dot material emitting red light, a quantum dot material emitting green light, and a quantum dot material emitting blue light once, and irradiating with the light of the first wavelength band once, the second ligand Y′ (Y1′) of the functional layer 3 can be crosslinked with the first ligand Y (Y1) contained in the quantum dot material emitting red light, the second ligand Y′ (Y2′) of the functional layer 3 can be crosslinked with the first ligand Y (Y2) contained in the quantum dot material emitting green light, and the second ligand Y′ (Y3′) of the functional layer 3 can be crosslinked with the first ligand Y (Y3) contained in the quantum dot material emitting blue light, which can simplify the manufacturing process of forming a plurality of pattern portions having different light emission colors.

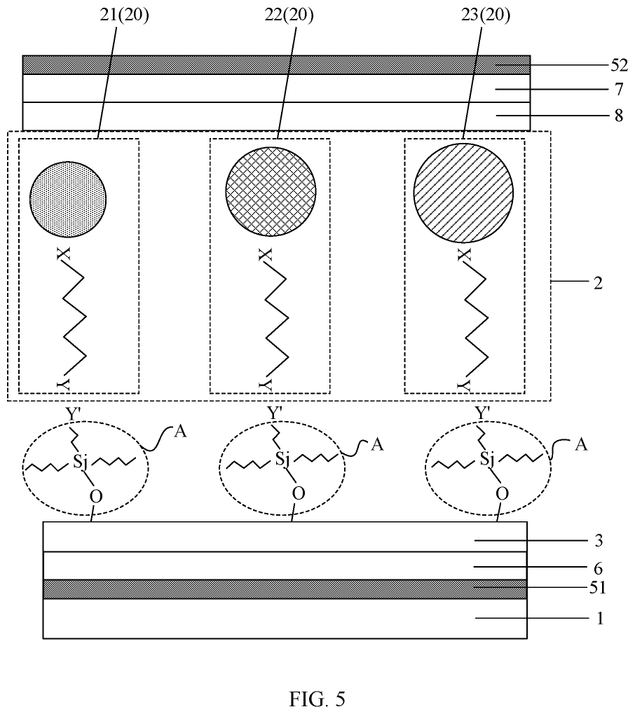

In one possible embodiment, as shown in FIG. 5, one side, facing the functional layer 3, of the substrate 1 may also be provided with a first electrode layer 51, and one side, deviating from the functional layer 3, of the quantum dot film layer 2 may also be provided with a second electrode layer 52. Optionally, the quantum dot light-emitting device may be an inverted QLED device, the first electrode layer 51 may be a cathode layer, the second electrode layer 52 may be an anode layer, the functional layer 3 may be an electron transport layer, an electron injection layer 6 may also be arranged between the functional layer 3 and the first electrode layer 51, a hole transport layer 8 may also be arranged between the quantum dot film layer 2 and the second electrode layer 52, and a hole injection layer 7 may also be arranged between the hole transport layer 8 and the second electrode layer 52. Optionally, the quantum dot light-emitting device may also be an upright QLED device, the first electrode layer 51 may also be an anode layer, the second electrode layer 52 may also be a cathode layer, the functional layer 3 may also be a hole transport layer, a hole injection layer may also be arranged between the functional layer 3 and the first electrode layer 51, an electron transport layer may also be arranged between the quantum dot film layer 2 and the second electrode layer 52, and a hole injection layer may also be arranged between the electron transport layer and the second electrode layer 52.

Some embodiments of the present disclosure also provide a display device, including the quantum dot light-emitting device provided by embodiments of the present disclosure.

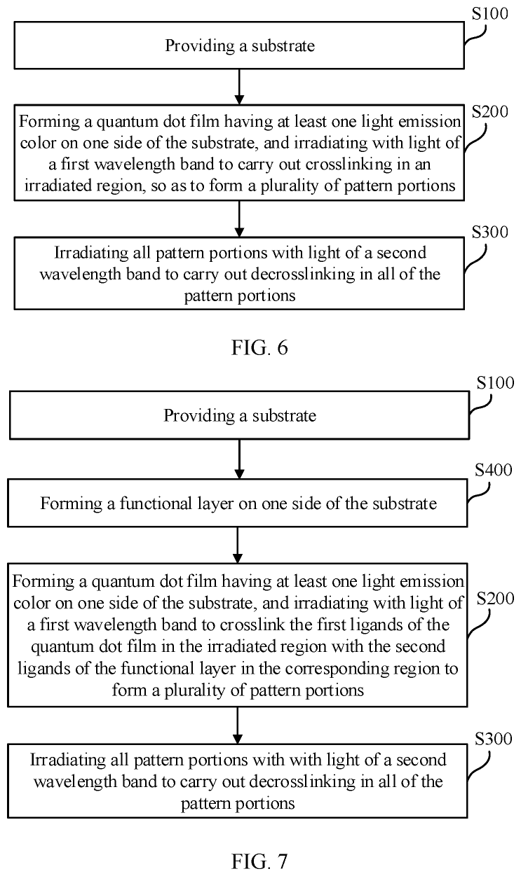

Based on the same inventive concept, some embodiments of the present disclosure provide a manufacturing method for the quantum dot light-emitting device provided by embodiments of the present disclosure, referring to FIG. 6, including:
a step S100, providing a substrate;
a step S200, forming a quantum dot film having at least one light emission color on one side of the substrate, and irradiating with light of a first wavelength band to carry out crosslinking in an irradiated region, so as to form a plurality of pattern portions; and
a step S300, irradiating all of the pattern portions with light of a second wavelength band to carry out decrosslinking in all of the pattern portions.

In one possible embodiment, patterning of the quantum dot film layer may be achieved by crosslinking between different ligands within the quantum dot film layer. Optionally, with respect to the step S200, forming the quantum dot film having at least one light emission color on one side of the substrate, and irradiating with the light of the first wavelength band to carry out crosslinking in the irradiated region, so as to form the plurality of the pattern portions includes:
forming the quantum dot film having at least one light emission color on one side of the substrate, and irradiating with the light of the first wavelength band to crosslink different ligands within the quantum dot film in the irradiated region to form the plurality of the pattern portions.

In one possible embodiment, patterning of the quantum dot film layer can also be achieved by crosslinking the first ligands of the quantum dot film layer with the second ligands of the functional layer. Optionally, referring to FIG. 7, before the step S200, prior to forming the quantum dot film having at least one light emission color on one side of the substrate, the manufacturing method further includes a step S400, forming a functional layer on one side of the substrate, wherein one side, deviating from the substrate, of the functional layer is connected with siloxane bodies and second ligands connected with the siloxane bodies.

Correspondingly, with regard to the step S200, forming the quantum dot film having at least one light emission color on one side of the substrate, and irradiating with the light of the first wavelength band to carry out crosslinking in the irradiated region, so as to form the plurality of the pattern portions includes: forming the quantum dot film having at least one light emission color on one side of the substrate, and irradiating with the light of the first wavelength band to crosslink the ligands of the quantum dot film in the irradiated region with the second ligands of the functional layer in the corresponding region to form the plurality of the pattern portions.

In one possible embodiment, when the pattern portions having different light emission colors are formed, each time a quantum dot film having one light emitting color is formed, irradiating with the light of the first wavelength band is performed once to form the pattern portion of this light emission color. Optionally, with regard to the step S400, forming the functional layer on one side of the substrate includes: forming the functional layer having the same second ligands corresponding to the pattern portions having different light emission colors on one side of the substrate.

Correspondingly, with respect to the step S200, forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions includes: during forming the quantum dot film of each light emission color, irradiating with the light of the first wavelength band through shielding of a mask to crosslink the first ligands of the quantum dot film in the irradiated region with the second ligands of the functional layer in the corresponding region, and removing the quantum dot film where crosslinking is not carried out to form the plurality of the pattern portions having one light emission color; and
repeating the above steps for a plurality of times to form the pattern portions having a plurality of light emission colors.

In one possible embodiment, when the pattern portions having different light emission colors are formed, the quantum dot film layer containing a plurality of light emission colors may be formed at one time, and one-time irradiation with the light of the first wavelength band is performed to form the plurality of the pattern portions having different light emission colors. Optionally, with regard to the step S400, forming the functional layer on one side of the substrate includes: forming the functional layer having different second ligands corresponding to the pattern portions having different light emission colors on one side of the substrate.

Forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions includes:
forming a plurality of quantum dot films having different light emission colors;
irradiating with the light of the first wavelength band once to crosslink the second ligands of the functional layer in different regions with the ligands of the quantum dot films in corresponding regions; and
removing the quantum dot films where crosslinking is not carried out to form the plurality of the pattern portions.

In order to more clearly understand the manufacturing method for the quantum dot light-emitting device provided by embodiments of the present disclosure, further details are described as follows.

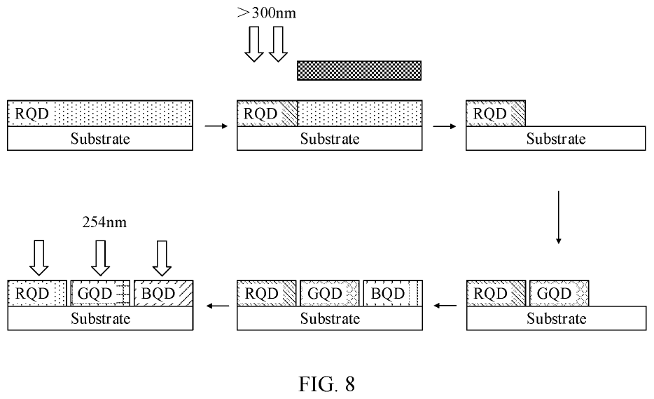

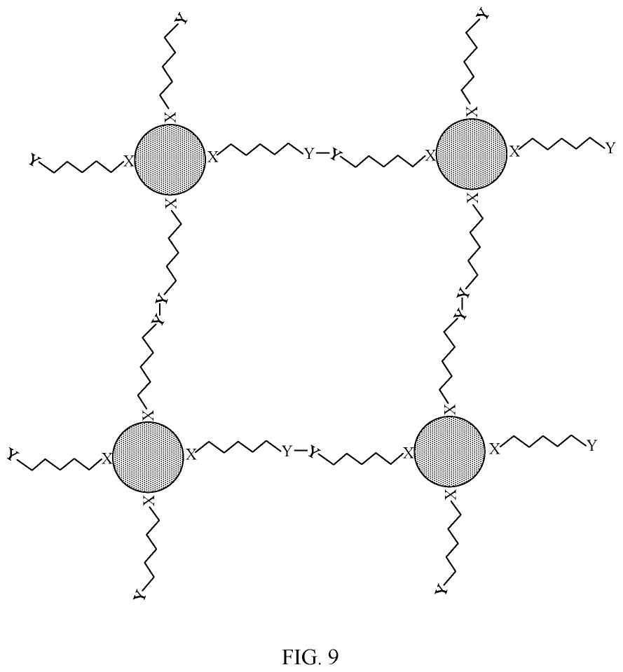

Embodiment 1: as shown in FIG. 8:
step 1, a red quantum dot film RQD emitting red light is deposited, under the shielding of the mask, irradiating with light of a first wavelength band of 300-350 nm (e.g., light of 300 nm) is performed to crosslink the different first ligands within the quantum dot film in the irradiated region, as shown in FIG. 9, afterwards, washing is performed, in the region where crosslinking is carried out, the quantum dot film is not easily removed during washing, and the quantum dot film is removed in the non-irradiated region where crosslinking is not carried out, thereby achieving patterning of the red quantum dot film RQD;
step 2, a green quantum dot film GQD emitting green light is deposited, under the shielding of the mask, irradiating with light of 300 nm is performed to crosslink the different first ligands within the quantum dot film in the irradiated region, afterwards, washing is performed, in the region where crosslinking is carried out, the quantum dot film is not easily removed during washing, and the quantum dot film is removed in the non-irradiated region where crosslinking is not carried out, thereby achieving patterning of the green quantum dot film GQD;
step 3, a blue quantum dot film BQD emitting blue light is deposited, under the shielding of the mask, irradiating with light of 300 nm is performed to crosslink the different first ligands within the quantum dot film in the irradiated region, afterwards, washing is performed, in the region where crosslinking is carried out, the quantum dot film is not easily removed during washing, and the quantum dot film is removed in the non-irradiated region where crosslinking is not carried out, thereby achieving patterning of the blue quantum dot film BQD; and
step 4, overall irradiation with light of a second wavelength band of 250-260 nm (e.g., light of 254 nm) is performed to restore the original structure of the quantum dots.

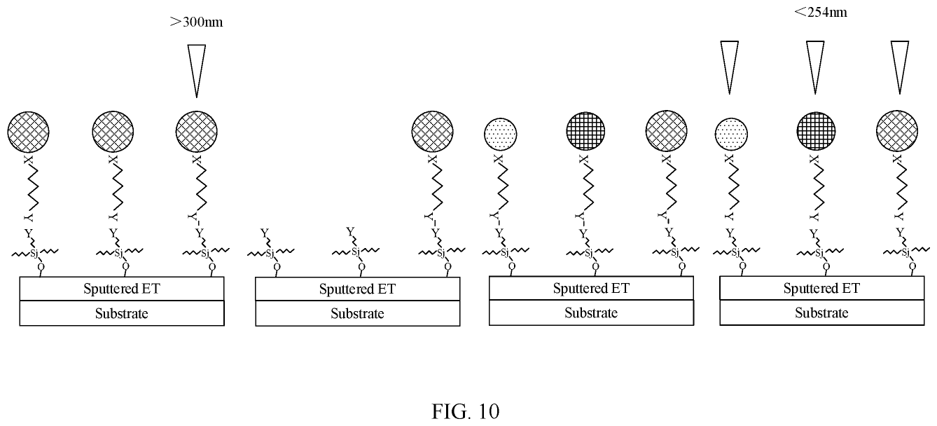

Embodiment 2, as shown in FIG. 10, the crosslinking and decrosslinking reactions are carried out through the interaction of the first ligands of the quantum dots and the second ligands of the functional layer 3;
step 1, siloxane bodies containing second ligands (the second ligands may be the same as the first ligands Y of the quantum dot film layer) at a terminal end thereof are formed on one side, deviating from the substrate (base), of the functional layer (optionally, an electron transport layer ET);
step 2, coating with the quantum dot film is performed, wherein the quantum dot film also contains the first ligands Y at a terminal end thereof;
step 3, irradiating with light of 300 nm is performed by using a mask with a certain pattern to crosslink the second ligands of the functional layer in the irradiated region with the first ligands of the quantum dot film;
step 4, the quantum dot film where crosslinking is not carried out is washed away by a solvent to form patterns;
step 5, the steps 2-4 are repeated to form quantum dots of the desired color in the remaining sub-pixels; and
step 6, after full patterning of the quantum dot film layer, irradiation with light of 254 nm is performed to decrosslink the crosslinked Y-Y structure to restore the original structure.

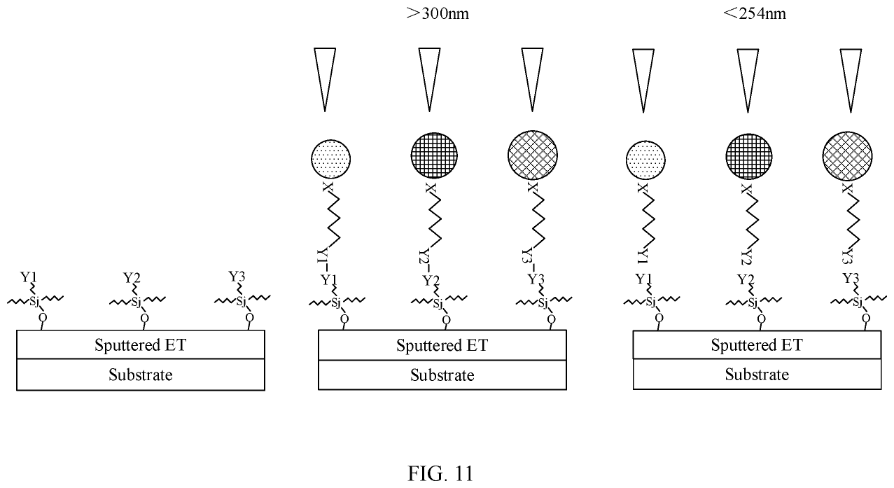

Embodiment 3, as shown in FIG. 11, the first ligands of red, green and blue quantum dots are specifically bound with the second ligands containing Y1, Y2 and Y3 in the functional layer with a system containing Y1, Y2 and Y3 respectively to form red, green and blue patterned quantum dots at one time;
step 1, inkjet printing or other patterning means is used to form a self-assembled monolayer on one side, deviating from the substrate, of the functional layer (optionally, an electron transport layer ET) in the red, green and blue sub-pixels, wherein the components of the self-assembled monolayer include siloxanyl chains containing Y1, Y2, Y3 groups at terminal ends thereof. Optionally, separately depositing different self-assembled monolayers in different sub-pixels of the functional layer may include: step 1, coating with a layer of photoresist is performed, after exposure development, red sub-pixel areas are exposed, the blue and green sub-pixel areas are still covered by the photoresist, coating with a solution of siloxanyl chains containing Y1 groups is performed, and the photoresist is stripped after the solution of the siloxanyl chains is bound with the substrate to form the desired self-assembled monolayers; and step 2, the step 1 is repeated to separately deposit the self-assembled monolayers containing Y2, and Y3 groups in the green and blue sub-pixels;
step 2, one-time coating with red, green and blue quantum dots is performed, optionally, quantum dots of different light emission colors are mixed directly together; the first ligands of the red, green, blue quantum dots use a system containing Y1, Y2, and Y3;
step 3, by irradiating with the light of the first wavelength band of 300 nm, only the ends of Y1-Y1, Y2-Y2 and Y3-Y3 in the red, green and blue sub-pixel areas are cross-linked, so only the green and blue quantum dots are bound with the functional layer in the red, green and blue sub-pixels;
step 4, the non-crosslinked quantum dots is washed away by a solvent to form patterns; and
step 5, after full patterning of the quantum dots, irradiation with light of 254 nm is performed to decrosslink the crosslinked structure, so as to restore the original structure.

The beneficial effects of embodiments of the present disclosure are as follows: according to the quantum dot material provided by embodiments of the present disclosure, the first ligands form a reversible photoresponsive crosslinking system, and may be crosslinked when irradiated with the light of the first wavelength band, and decrosslinked when irradiated with the light of the second wavelength band, so that when the patterned quantum dot film layer is formed by the quantum dot material provided by embodiments of the present disclosure, in the patterning process, crosslinking may be carried out in the irradiated region by irradiating with the light of the first wavelength band, so the quantum dot material is not easily removed during subsequent cleaning, while the quantum dot material in a region where crosslinking is not carried out can be removed during cleaning, thereby realizing patterning of the quantum dot film layer, after patterning, decrosslinking may be carried out in the region where crosslinking is carried out by irradiating with the light of the second wavelength band, thereby realizing the patterning of the quantum dot film layer, and while avoiding the influence of the crosslinked structure on the carrier transport performance, so as to improve the problems in the prior art that carrier transport is hindered, the electrical performance of the device is reduced, and the luminous efficiency is reduced after the quantum dot film layer is patterned.

Obviously, those skilled in the art can make various changes and modifications to the present disclosure without departing from the spirit and scope of the present disclosure. Thus, if these changes and modifications of the present disclosure fall within the scope of the claims of the present disclosure and its equivalent technology, the present disclosure is also intended to include these changes and modifications.

What is claimed is:

1. A quantum dot material, comprising: a quantum dot body, a linker, and a first ligand; wherein one end of the linker is connected with the quantum dot body, and the other end of the linker is connected with the first ligand; and the first ligand comprises one or a combination of: 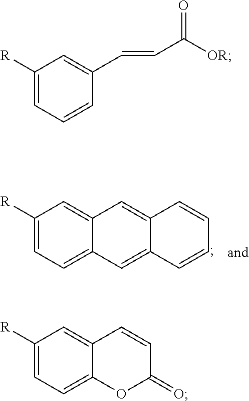
wherein R comprises one or a combination of:
an alkyl chain;
an aromatic ring; and
a heterocycle.

2. The quantum dot material according to claim 1, wherein the linker comprises a first connection structure, and a second connection structure; one end of the first connection structure is connected with the quantum dot body, and the other end of the first connection structure is connected with one end of the second connection structure; and the other end of the second connection structure is connected with the first ligand.

3. The quantum dot material according to claim 2, wherein the first connection structure comprises one of:
—SH;
—COOH; or
—NH₂.

4. The quantum dot material according to claim 2, wherein the second connection structure comprises an alkyl chain.

5. A quantum dot light-emitting device, comprising: a substrate, and a quantum dot film layer located at one side of the substrate and having a plurality of pattern portions; wherein each of the pattern portions comprises the quantum dot material according to claim 1.

6. The quantum dot light-emitting device according to claim 5, wherein first ligands of the pattern portions are crosslinked with each other within the pattern portions in response to the first ligands being irradiated with light of a first wavelength band, and decrosslinked in response to the first ligands being irradiated with light of a second wavelength band.

7. The quantum dot light-emitting device according to claim 5, wherein a functional layer is arranged between the substrate and the quantum dot film layer; one side, facing the quantum dot film layer, of the functional layer is connected with a siloxane body and a second ligand connected with the siloxane body; and
the first ligand of the pattern portions is identical to the second ligand in a corresponding region.

8. The quantum dot light-emitting device according to claim 7, wherein the first ligand of the pattern portions is crosslinked with the second ligand in the corresponding region in response to the first ligand and the second ligand being irradiated with light of a first wavelength band and the first ligand and the second ligand are decrosslinked in response to the first ligand and the second ligand being irradiated with light of a second wavelength band.

9. The quantum dot light-emitting device according to claim 7, wherein the quantum dot light-emitting device comprises at least two types of the pattern portions having different light emission colors, the first ligands of all of the pattern portions are identical with each other, and all of the second ligands of the functional layer are identical with each other.

10. The quantum dot light-emitting device according to claim 7, wherein the quantum dot light-emitting device comprises at least two types of the pattern portions having different light emission colors, the first ligands of the pattern portions having same light emission color are identical to each other, and the first ligands of the pattern portions having different light emission colors are different from each other.

11. The quantum dot light-emitting device according to claim 7, wherein a first electrode layer is arranged between the substrate and the functional layer, and a second electrode layer is arranged at one side, deviating from the functional layer, of the quantum dot film layer.

12. A display device, comprising the quantum dot light-emitting device according to claim 5.

13. A manufacturing method for the quantum dot light-emitting device according to claim 5, comprising:
providing a substrate;
forming a quantum dot film having at least one light emission color on one side of the substrate, and irradiating with light of a first wavelength band to carry out crosslinking in an irradiated region, so as to form a plurality of pattern portions; and
irradiating the pattern portions with light of a second wavelength band to carry out decrosslinking in the pattern portions.

14. The manufacturing method according to claim 13, wherein the forming the quantum dot film having at least one light emission color on one side of the substrate, and irradiating with the light of the first wavelength band to carry out crosslinking in the irradiated region, so as to form the plurality of the pattern portions comprises:
forming the quantum dot film having at least one light emission color on one side of the substrate, and irradiating with the light of the first wavelength band to crosslink different first ligands within the quantum dot film in the irradiated region to form the plurality of the pattern portions.

15. The manufacturing method according to claim 13, wherein before the forming the quantum dot film having at least one light emission color on one side of the substrate, the manufacturing method further comprises: forming a functional layer on one side of the substrate, wherein one side, deviating from the substrate, of the functional layer is connected with siloxane bodies and second ligands connected with the siloxane bodies; and
The forming the quantum dot film having at least one light emission color on one side of the substrate, and irradiating with the light of the first wavelength band to carry out crosslinking in the irradiated region, so as to form the plurality of the pattern portions comprises:
forming the quantum dot film having at least one light emission color on one side of the substrate, and irradiating with the light of the first wavelength band to crosslink the first ligands of the quantum dot film in the irradiated region with the second ligands of the functional layer in a corresponding region to form the plurality of the pattern portions.

16. The manufacturing method according to claim 15, wherein the forming the functional layer on one side of the substrate comprises: forming the functional layer on one side of the substrate so that the functional layer and the pattern portions having different light emission colors correspond to same second ligands ;
forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions comprises:
irradiating with the light of the first wavelength band through shielding of a mask to crosslink the first ligands of the quantum dot film in the irradiated region with the second ligands of the functional layer in the corresponding region, during forming the quantum dot film of each light emission color, and removing the quantum dot film where crosslinking is not carried out to form the plurality of the pattern portions having one light emission color; and
repeating above steps for a plurality of times to form the pattern portions having a plurality of light emission colors.

17. The manufacturing method according to claim 15, wherein the forming the functional layer on one side of the substrate comprises: forming the functional layer on one side of the substrate so that the functional layer and the pattern portions having different light emission colors corresponds to different second ligands; and
the forming the quantum dot film having at least one light emission color on one side of the substrate, and irradiating with the light of the first wavelength band to crosslink the first ligands of the quantum dot film in the irradiated region with the second ligands of the functional layer in the corresponding region to form the plurality of the pattern portions comprises:
forming a plurality of quantum dot films having different light emission colors;
irradiating with the light of the first wavelength band to crosslink the second ligands of the functional layer in different regions with the first ligands of the quantum dot films in corresponding regions; and
removing the quantum dot films where crosslinking is not carried out to form the plurality of the pattern portions.
